(19) United States
(12) Patent Application Publication
(10) Pub. No.: US 2024/0371662 A1
(43) Pub. Date: Nov. 7, 2024

(54) METHOD, SYSTEM AND APPARATUS FOR SURFACE MODIFICATION

(71) Applicant: ASM IP Holding B.V., Almere (NL)

(72) Inventors: Rajkumar Jakkaraju, Phoenix, AZ (US); Paul Ma, Scottsdale, AZ (US); Yi Zhang, Scottsdale, AZ (US); Dong Li, Phoenix, AZ (US)

(21) Appl. No.: 18/651,935

(22) Filed: May 1, 2024

Related U.S. Application Data
(60) Provisional application No. 63/464,485, filed on May 5, 2023.

(51) Int. Cl. H01L 21/67; H01J 37/32; H01L 21/687

(52) U.S. Cl. CPC H01L 21/67069; H01J 37/32357; H01J 37/32449; H01L 21/68714; H01J 2237/334

(57) ABSTRACT

Described herein are example, method, system and apparatus for supporting a substrate in a chamber wherein the substrate comprises a surface, contacting the surface of the substrate with an excited species within the chamber, contacting the surface of the substrate with an etchant species within the chamber and removing organic residue or non-organic residue, or a combination thereof, from the surface of the substrate responsive to executing the above steps.

### CROSS-REFERENCE TO RELATED APPLICATIONS

This application is a nonprovisional of, and claims priority to and the benefit of, U.S. Provisional Patent Application No. 63/464,485, filed May 5, 2023 and entitled “METHOD, SYSTEM AND APPARATUS FOR SURFACE MODIFICATION,” which is hereby incorporated by reference herein.

### FIELD OF THE DISCLOSURE

The present invention relates to the fabrication of integrated circuits, particularly to methods and apparatuses for pre-cleaning a substrate surface.

### BACKGROUND OF THE DISCLOSURE

Fabrication of integrated circuits often can involve formation of one or more material layers on a substrate surface. These material layers can include, for example, mono-crystalline, polycrystalline, and/or amorphous material layers. Formation of the material layers can be achieved using various thin film deposition techniques, including various physical (e.g., physical sputtering) and/or chemical (e.g., chemical vapor deposition, atomic layer deposition, and/or epitaxial deposition) deposition techniques. For example, mono-crystalline material formation on a substrate surface can be performed using an epitaxial deposition process, such as for formation of mono-crystalline semiconductor materials (e.g., mono-crystalline silicon).

The presence of unwanted material (e.g., a native oxide layer, residue from upstream processing, and/or other contaminants) on the substrate surface may interfere with formation of a desired material layer over that substrate surface. For example, the intervening material may cause introduction of an increased number of defects in the structure of the desired material layer and/or may adversely affect an electrical performance of the desired material layer.

In some embodiments, an intervening material such as a native oxide material may form on a substrate surface due to exposure of the substrate to oxygen during the integrated circuit fabrication process (e.g., exposure to ambient air during transfer of the substrate between fabrication systems, and/or to residual oxidizing agents within fabrication systems). Removal or such unwanted material may be time consuming and may have a negative impact on throughput.

Accordingly, there is a continuing need for methods, systems for removing unwanted material from the substrate surface that minimize or reduce negative impacts on throughput. The present disclosure provides a solution to this need.

### SUMMARY OF THE DISCLOSURE

In an aspect, an example method is provided comprising, supporting a substrate in a chamber wherein the substrate comprises a surface, contacting the surface of the substrate with an excited species within the chamber, contacting the surface of the substrate with an etchant species within the chamber, and removing organic residue or non-organic residue, or a combination thereof, from the surface of the substrate responsive to executing the above noted steps of contacting the surface of the substrate with an excited species within the chamber, contacting the surface of the substrate with an etchant species within the chamber.

In various examples, the etchant species may be a reducing species, an oxidizing species, a halide, alcohol containing species, oxygen containing species, chalcogen, formaldehyde or a combination thereof. In various examples, the excited species comprises a radical comprising hydrogen, argon, nitrogen, fluorine, chlorine, or oxygen or a combination thereof. In various examples, the excited species comprises an ion comprising hydrogen, argon, neon, krypton, nitrogen, helium, xenon, radon, chlorine, fluorine, or oxygen or a combination thereof.

The method may include purging the chamber. In an example, the noted steps of contacting the surface of the substrate with an excited species within the chamber, purging the chamber and contacting the surface of the substrate with an etchant species within the chamber, may be performed in any order. In an example, certain steps are optional, or may be repeated in any sequence. The steps may be repeated in cycles. In an example, a first cycle including contacting the surface of the substrate with an excited species may be performed over a first time period, T1 and a second cycle including contacting the surface of the substrate with an etchant species may be performed over a second time period, T2. In an example, T1 may be greater than T2. The excited species may be generated by a remote plasma unit in fluid communication with the chamber. In an example, inert gas may be flowed at a positive pressure from the remote plasma unit into the chamber during T2 optionally wherein the inert gas may be flowed into the chamber during T2 for a time less than the entire second time period, T2. In an example, the inert gas curtain may be flowed into the chamber over the entire second time period, T2.

In an aspect, an example substrate processing system is provided comprising a first reaction chamber including a first substrate support for supporting a first substrate, a first plasma source in fluid communication with the first reaction chamber and a first delivery vessel in fluid communication with the first reaction chamber. In an example, the substrate processing system may further comprise a second reaction chamber including a second substrate support for supporting a second substrate, a second plasma source in fluid communication with the second reaction chamber, the first delivery vessel in fluid communication with the second reaction chamber, and a second delivery vessel in fluid communication with the first reaction chamber and the second reaction chamber. In an example, the first plasma source and the second plasma source may comprise a first remote plasma unit and a second remote plasma unit, respectively. In an example, the first remote plasma unit and the second remote plasma unit may be configured to generate radicals to contact the first substrate and the second substrate.

In an example, the substrate processing system may comprise a first transport tube coupled between the first remote plasma unit and the first reaction chamber, a second transport tube coupled between the second remote plasma unit and the second reaction chamber, a first chemical gas line coupled to the first delivery vessel, the first transport tube and the second transport tube, and/or a second chemical gas line coupled to the second delivery vessel, the first transport tube and the second transport tube. In another example, the substrate processing system may comprise a second reaction chamber including a second substrate support, the first remote plasma unit in fluid communication with the second reaction chamber, the first delivery vessel in fluid communication with the second reaction chamber and/or a second delivery vessel in fluid communication with the first reaction chamber and the second reaction chamber. In another example the first delivery vessel may be in fluid communication with the first reaction chamber via a first chemical gas line and/or the second delivery vessel may be in fluid communication with the second reaction chamber via a second chemical gas line. In an example, the first plasma source may be configured to generate ions within the first reaction chamber. In some examples, a gas distribution device or the first substrate support may comprise an electrode for forming the ions for a direct plasma surface treatment of the first substrate within the reaction chamber.

In an aspect, an example substrate processing system may comprise a reaction chamber including a substrate support for supporting a substrate wherein the substrate comprises a surface, a plasma source in fluid communication with the reaction chamber configured to contact the surface of the substrate with an excited species within the chamber, a delivery vessel in fluid communication with the reaction chamber configured to contact the surface of the substrate with an etchant species within the chamber, and a controller coupled to the reaction chamber, the plasma source, and the delivery vessel configured to control the plasma source and the delivery vessel so as to control removing organic residue or non-organic residue, or a combination thereof, from the surface of the substrate.

In an example, the substrate processing system may comprise a plurality of sensors, wherein the controller may be configured to control the removing the organic residue or the non-organic residue, or a combination thereof, from the surface of the substrate based on data from each of the plurality of sensors. In an example, the substrate processing system may comprise a vacuum pump configured to purge the reaction chamber subsequent to the excited species contacting the surface of the substrate, or subsequent to the etchant species contacting the surface of the substrate, or a combination thereof. In an example, the controller may be coupled to the vacuum pump and may be configured to control the purging of the chamber so as to control removing the organic residue or the non-organic residue, or a combination thereof, from the surface of the substrate.

The substrate processing system of claim 24, wherein the removing organic residue or non-organic residue, or a combination thereof, from the surface of the substrate is executed, by the controller, in at least a first cycle including flowing the excited species to the surface of the substrate from the plasma source in a first time period, T1 and a second cycle including flowing the etchant species to the surface of the substrate from the delivery vessel in a second time period, T2. In an example, T1 is greater than T2. The excited species may be a radical or an ion or may include a radical and an ion. In an example, the substrate processing system may comprise the plasma source is a remote plasma unit. In an example, the plasma source is a direct plasma source and may include an electrode in within the reaction chamber configured to generate a direct plasma.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1A is a schematic diagram illustrating an example substrate processing system;

FIG. 1B is a diagram illustrating an example substrate having a top, side and bottom surface;

FIG. 1C is a schematic diagram illustrating an example substrate processing system;

FIG. 2 is a flow chart illustrating an example of a process for removing material from a surface of a substrate;

FIG. 3A is a schematic diagram illustrating an example substrate processing system;

FIG. 3B is a diagram illustrating an example substrate having a top, side and bottom surface;

FIG. 3C is a schematic diagram illustrating an example substrate processing system;

FIG. 4 is a flow chart illustrating an example of a process for removing material from a surface of a substrate;

FIG. 5 is a schematic diagram illustrating an example process for removing material from a surface of a substrate;

FIG. 6 is a schematic diagram illustrating an example process for removing material from a surface of a substrate;

FIG. 7 is a schematic diagram illustrating an example process for removing material from a surface of a substrate;

FIG. 8 is a schematic diagram illustrating an example process for removing material from a surface of a substrate; and

FIG. 9 is a schematic diagram illustrating an example process for removing material from a surface of a substrate.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

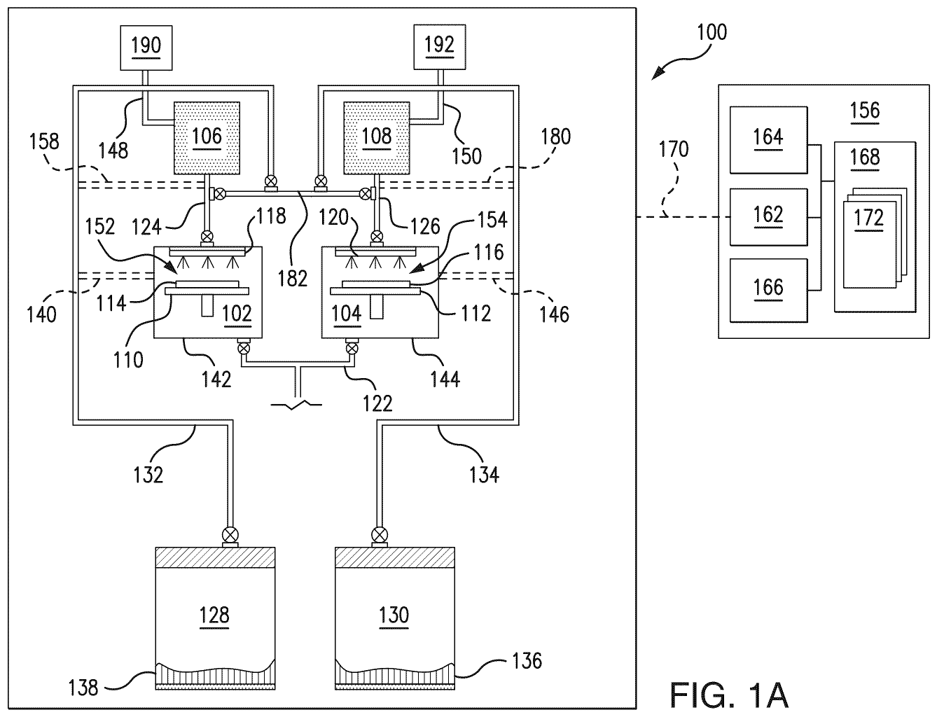

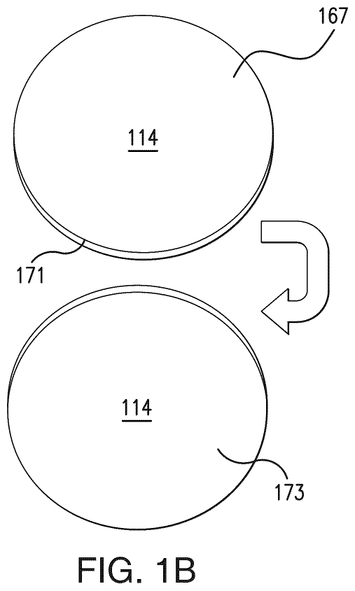

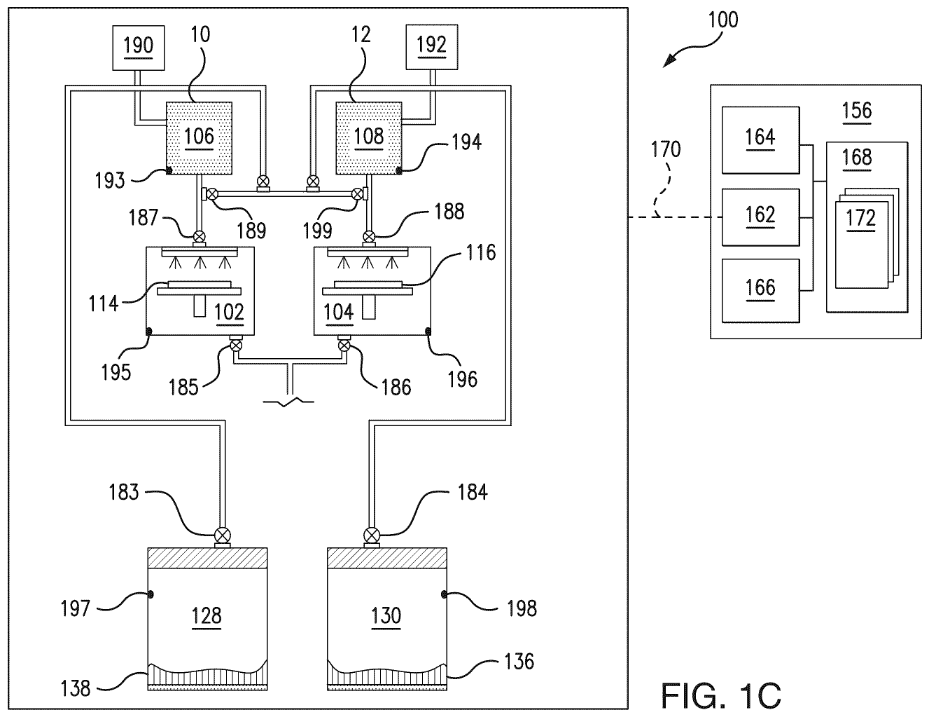

FIG. 1A is a schematic diagram illustrating an example substrate processing system 100 configured to perform one or more substrate cleaning operations. Substrate processing system 100 includes a dual chamber module having two reaction chambers. In other examples, substrate processing system 100 may comprise a single chamber or any other number of chambers and claimed subject matter is not limited in this regard. For example, substrate processing system 100 may be a quad chamber module including four reaction chambers.

In an example, reaction chambers 102 and 104 may include respective susceptors 110 and 112 to support respective substrates 114 and 116 during surface cleaning, processing operations and/or other operations. Reaction chamber 102 may be coupled to remote plasma unit 106 via transport tube 124 putting reaction chamber 102 in fluid communication with remote plasma unit 106. Reaction chamber 104 may be coupled to remote plasma unit 108 via transport tube 126 putting reaction chamber 104 in fluid communication with remote plasma unit 108.

Remote plasma units 106 and 108 may be coupled to respective chemical source vessels 190 and/or 192 supplying a vapor phase reactant via respective chemical delivery lines 148 and 150. The vapor phase reactant may be activated by remote plasma unit 106 and/or remote plasma unit 108 to generate an excited species, such as radicals of hydrogen, argon, nitrogen, fluorine, oxygen, nitrogen trifluoride, chlorine, or the like, or a combination thereof to be used in one or more substrate cleaning operations (e.g., cleaning a surface of substrate 114 or 116). Other radical species may be used and claimed subject matter is not limited in this regard. For simplicity, the term “excited species” used herein can be understood to encompass electrons, ions, radicals, atoms or other excited species that can, for example, be generated by a plasma. Typically, the excited species are formed in a plasma discharge and depending on how they are supplied to the reaction space where a substrate is supported the excited species may comprise electrons, ions, radicals and/or atoms, for example oxygen, hydrogen or nitrogen plasma, ions, radicals, atomic oxygen/hydrogen/nitrogen, or other excited species that can, for example, be generated by a plasma. In various embodiments excited species may be generated by coupling power, such as by RF alternated electrical fields, microwave standing waves, ultraviolet light, or other forms of energy, to the flowing vapor phase reactant from source vessels 190 and/or 192 that may be supplied to remote plasma unit 106 and/or remote plasma unit 108 via respective chemical delivery lines 148 and 150.

Substrate processing system 100 includes gas distribution systems 118 and 120 to distribute a substance (e.g., one or more reactants, etchants and/or excited species) to respective surfaces of substrates 114 and 116. In an example, excited species generated during a plasma phase in either of remote plasma units 106 and 108 may be delivered to respective reaction chambers 102 and/or 104 via respective transport tubes 124 and/or 126. Excited species may contact a surface of substrate 114 within reaction space 152 and/or a surface of substrate 116 within reaction space 154.

Substrate processing system 100 may include a vacuum source 122 for controlling vacuum pressure in one or more of reaction chambers 102 and 104. In another example, each chamber may have a vacuum source, rather than a shared vacuum source 122. After or as part of a surface cleaning operation cycle, excited species may be removed from reaction chamber 102 and/or 104. Such removal can be accomplished in a variety of ways, e.g., by turning off the power that generates the excited species, and/or by physical removal of the excited species (e.g., by purging, pump down, moving the substrate away from a zone in which the excited species is supplied, or combinations thereof). Vacuum source 122 may perform pump down or other purging to remove excited species from reaction chambers 102 and/or 104.

In an example, substrate processing system 100 may include delivery vessels 128 and 130. Delivery vessels 128 and/or 130 may be configured to store and deliver respective chemical species 136 and/or 138 to one or both reaction chambers 102 and 104 via respective chemical delivery lines 132 and/or 134.

Chemical species 136 and/or 138 may be configured to remove unwanted residue from substrate 114 and/or 116 during a substrate surface cleaning operation. Chemical species 136 and/or 138 may comprise an etchant such as, for example: reducing and/or oxidizing species including: halides, fluorides, alcohols, amines, phosphines, alkenes, alkynes, carbon monoxide, β-diketone (e.g., acetylacetone, hexafluoroacetylacetone, and/or tetramethylheptanedione), alcohol containing species, oxygen containing species, chalcogen, or the like or combinations thereof or other chemical reactants configured to remove material from a substrate 114 and/or 116 surface.

Delivery vessel 128 may be coupled to transport tube 124 and/or 126 via chemical delivery line 132 coupled to chemical delivery line 182. This puts delivery vessel 128 in fluid communication with reaction chamber 102 and/or reaction chamber 104. Optionally, chemical delivery line 132 may be coupled to chemical delivery line 158 (connecting directly to transport tube 124). Chemical species 138 may be distributed to one or more of substrates 114 and 116 via respective gas distribution systems 118 and 120. Alternatively, or additionally, chemical species 138 may be distributed to one or more of substrate 114 via chemical delivery line 140 configured to open into an inner volume 142 of chamber 102. Distribution of chemical species 138 to substrate 114 may be through a crossflow reaction wherein chemical species 138 flows over substrate 114 within inner volume 142 of chamber 102.

Similarly, in an example, delivery vessel 130 may be configured to store and deliver a chemical species 136 to one or both reaction chambers 102 and 104. Chemical species 136 may be configured to remove unwanted residue from substrate 114 and/or 116. Chemical species 136 may comprise an etchant or other chemical reactant configured to remove material from a substrate surface such as a reducing and/or oxidizing species including: halides, fluorides, alcohols, amines, phosphines, alkenes, alkynes, carbon monoxide, β-diketone (e.g., acetylacetone, hexafluoroacetylacetone, and/or tetramethylheptanedione), formaldehyde), alcohol containing species, oxygen containing species, chalcogen, or the like or combinations thereof. Delivery vessel 130 may be coupled to transport tube 124 and/or 126 via chemical delivery line 134 coupled to chemical delivery line 182. This puts delivery vessel 130 in fluid communication with reaction chamber 102 and/or reaction chamber 104. Optionally, chemical delivery line 134 may be coupled to chemical delivery line 180 (connecting directly to transport tube 126). Chemical species 136 may be distributed to one or more of substrates 114 and 116 via respective gas distribution systems 118 and 120. Alternatively, or additionally, chemical species 136 may be distributed to substrate 116 via chemical delivery line 146 configured to open into an inner volume 144 of chamber 104. Distribution of chemical species 136 to substrate 116 may be through a crossflow reaction wherein chemical species 136 flows over substrate 116 within inner volume 144 of chamber 104.

FIG. 1B is a diagram of a substrate 114 having a top surface 167, side surface 171 and bottom surface 173. Top surface 167, side surface 171 and bottom surface 173 may have various textures and/or surface features in or on which unwanted material may be disposed. Such unwanted material may be removed from top surface 167, side surface 171 and bottom surface 173 according to methods, systems and apparatus described herein.

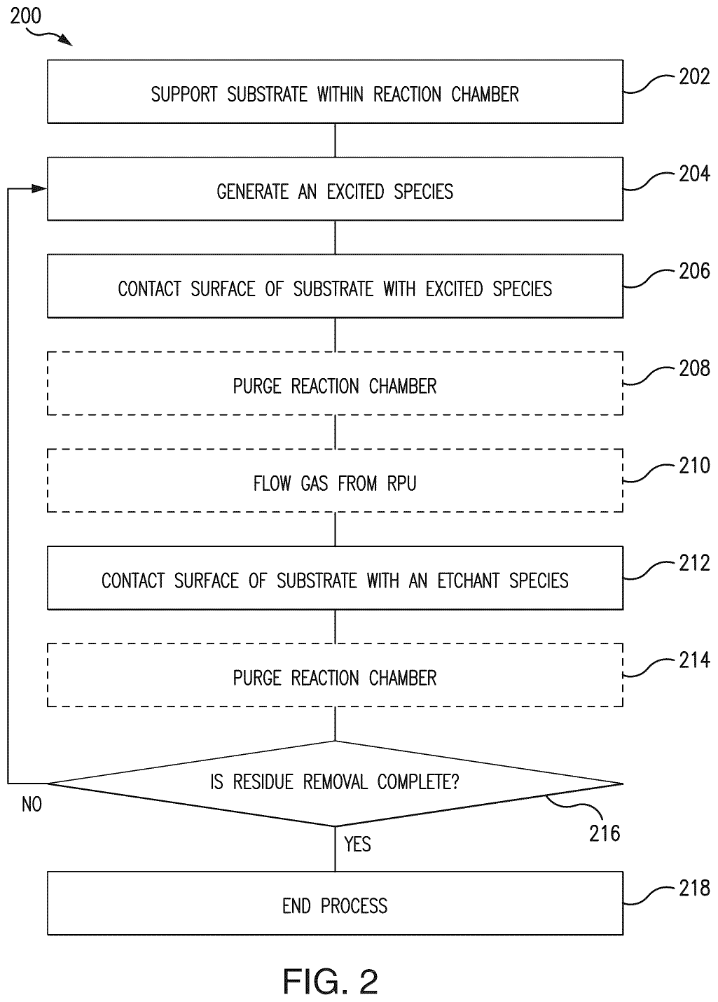

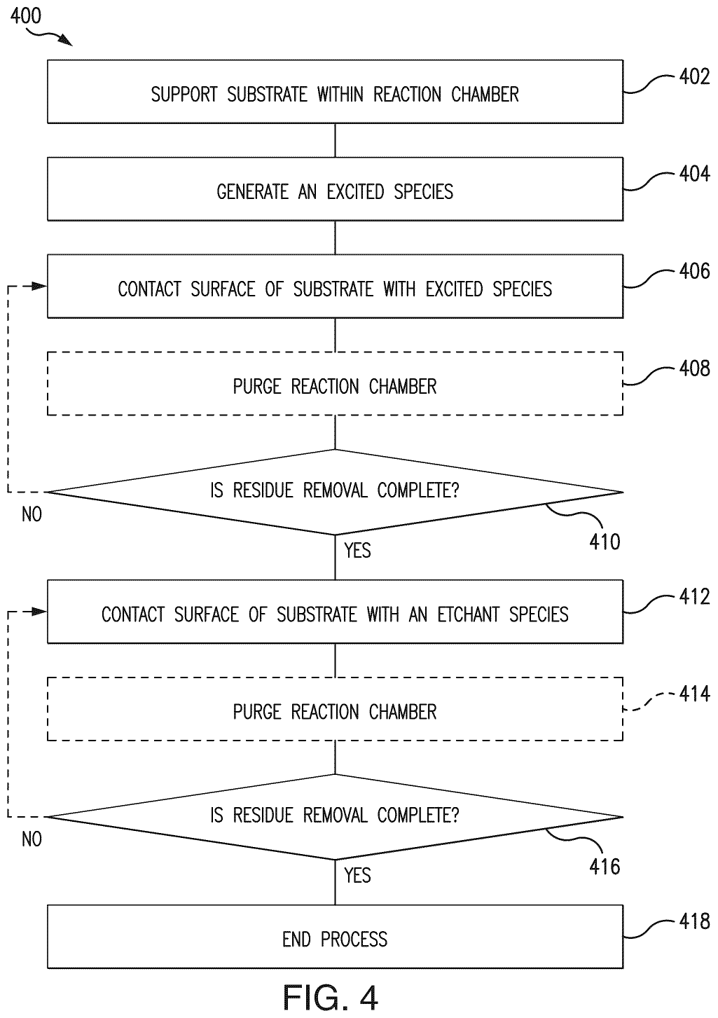

Referring now to FIG. 1C, in an example controller 156 includes a device interface 162, a processor 164, a user interface 166, and a memory 168. The device interface 162 connects the processor 164 to the wired or wireless link 170. The processor 164 may be operably connected to the user interface 166 (e.g., to receive user input and/or provide user output therethrough) and may be disposed in communication with the memory 168. The memory 168 includes a non-transitory machine-readable medium having a plurality of program modules 172 recorded thereon containing instructions that, when read by the processor 164, cause the processor 164 to execute certain operations. Among the operations are operations of a substrate surface cleaning process (shown in FIG. 2 and FIG. 4), as will be described.

In an example, controller 156 may be communicatively coupled to various devices within substrate processing system 100 including a reaction chamber (e.g., reaction chambers 102 and/or 104), a plasma source (e.g., remote plasma unit 106 and/or remote plasma unit 108), and/or a delivery vessel (e.g., delivery vessels 128 and/or 130) and may be configured to control the reaction chamber, plasma source and the delivery vessel so as to control removing organic residue or non-organic residue, or a combination thereof, from the surface of the substrate (e.g., substrates 114 and/or 116) during a substrate surface cleaning operation.

In an example, controller 156 may further be communicatively coupled to valves 183, 184, 185, 186, 187, 188, 189, and/or 199 and/or sensors 193, 194, 195, 196, 197 and/or 198. Controller 156 may be configured to selectively control the flow of various chemicals, excited species, etchant and/or other substances into or out of the respective reaction chambers, delivery vessels and/or remote plasma units via valves 183, 184, 185, 186, 187, 188, 189, and/or 199. For example, valves 183 and 184 may be used to control the flow of respective ones of chemical species 136 and/or 138 into respective reaction chambers 102 and/or 104, while valves 189 and/or 199 may control flow of chemical species 136 and/or 138 into respective transport tubes 124 and/or 126. Valves 187 and/or 188 may be used to control the flow of chemical species 136 and/or 138 and/or excited species 10 and/or 12 from respective remote plasma units 106 and/or 108 into respective reaction chambers 102 and/or 104. Valves 185 and/or 186 may control vacuum pump/purge operations to remove materials from reaction chambers.

In an example, controller 156 may control the flow (including flow rate and/or duration of flow) of excited species 10 and/or 12 (from remote plasma unit 106 and/or remote plasma unit 108), the flow (including flow rate and/or duration of flow) of respective chemical species 136 and/or 138 (from delivery vessels 128 and/or 130) and/or removal of one or more chemicals and/or excited species from reaction chambers (e.g., reaction chambers 102 and/or 104) via a vacuum pump (not shown).

In an example, controller 156 may be configured to receive input signals from sensors disposed throughout substrate processing system 100 such as sensors 193 and/or 194 (disposed within respective remote plasma units 106 and/or 108), sensors 195 and/or 196 (disposed within respective reaction chambers 102 and/or 104) and/or sensors 197 and/or 198 (disposed within respective delivery vessels 128 and/or 130). Such sensors may provide feedback data to controller 156, which can adjust various device parameters of the devices communicatively couple to controller 156 responsive to the feedback data. In some examples, sensors 193, 194, 195, 196, 197 and/or 198 may comprise pressure sensors, light sensors, temperature sensors, flow rate sensors and/or composition sensors, or the like or a combination thereof.

In operation, the controller 156 receives feedback data from one or more of the sensors (e.g., sensors 193, 194, 195, 196, 197 and/or 198) and uses the feedback data to determine how to adjust device parameters to control the substrate surface cleaning process described in FIGS. 2 and 4. In an example the controller 156 may adjust the device parameters based on a set of predetermined instructions or based on real time feedback from sensors 193, 194, 195, 196, 197 and/or 198. As will be appreciated by those of skill in the art in view of the present disclosure, the controller 156 may have a different arrangement in other examples and remain within the scope of the present disclosure.

FIG. 2 is a flow chart that depicts an example substrate surface cleaning process 200 for removing organic residue and/or non-organic residue from a surface of a substrate (e.g., substrate 114 and/or substrate 116). In an example, process 200 will be described with reference to FIG. 1.

Process 200 may begin at block 202, where the substrate may be supported by a susceptor (e.g., susceptor 110 and/or susceptor 112) in a reaction chamber (e.g., reaction chamber 102 and/or reaction chamber 104) wherein the substrate comprises a surface.

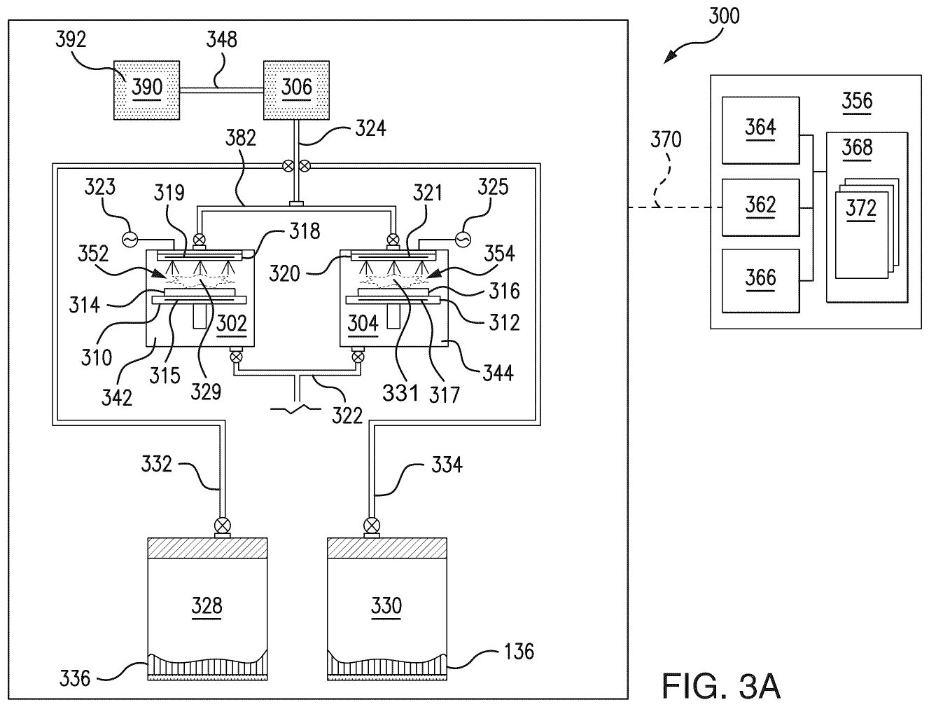

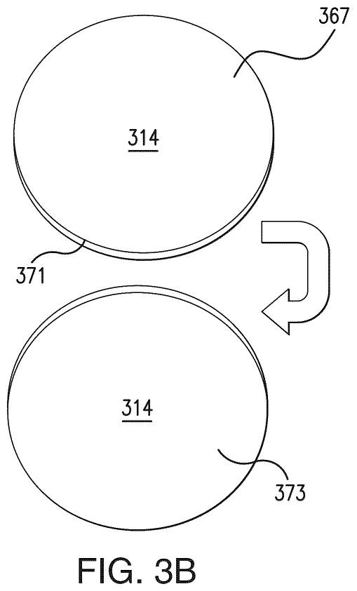

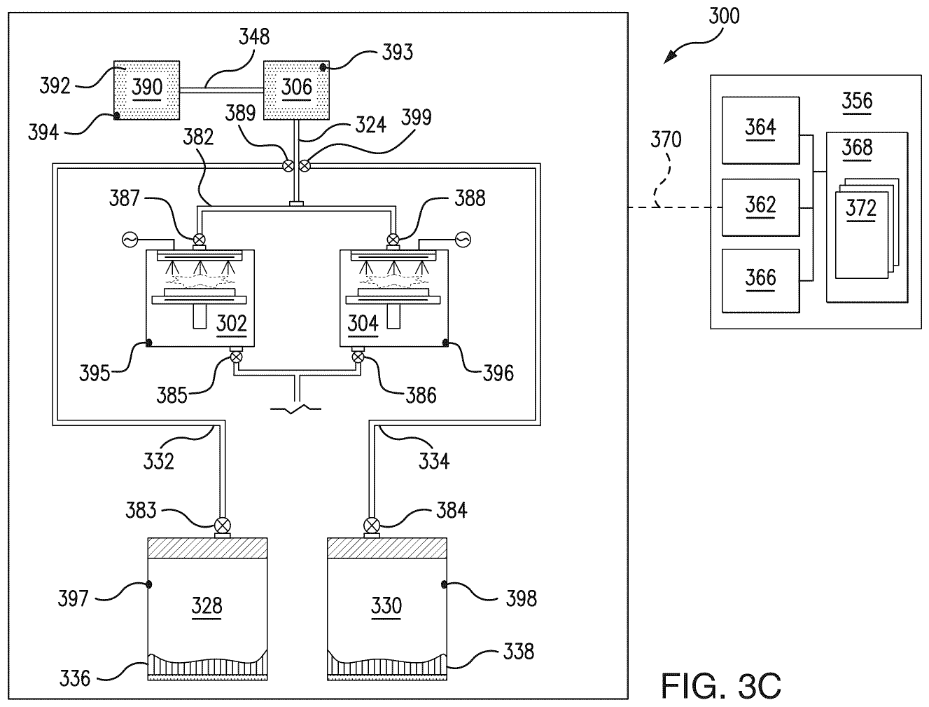

Process 200 may continue at block 204, where an excited species may be generated in a plasma. In an example, the excited species comprises a radical. Such radical may comprise hydrogen, argon, nitrogen, fluorine, chlorine, or oxygen or a combination thereof. The excited species may be generated by a remote plasma unit (e.g., remote plasma unit 106 and/or remote plasma unit 108) in fluid communication with the chamber. In another example, the excited species may be generated in a direct plasma and may comprises ions as described with respect to FIG. 3A hereinbelow. Such ions may comprise hydrogen, argon, neon, krypton, nitrogen, helium, xenon, radon, chlorine, fluorine, oxygen, or the like, or a combination thereof.

At block 206, the surface of the substrate may be contacted with the excited species within the chamber. At block 208, the reaction chamber may be purged to remove excess excited species and/or byproducts of residue removal.

At block 210, an inert gas curtain comprising a positive pressure flow from an remote plasma unit (e.g., remote plasma unit 106 and/or remote plasma unit 108) may be flowed into the chamber to prevent contamination in the remote plasma unit by the etchant and/or residue removal byproducts.

At block 212, the surface of the substrate may be contacted with an etchant species within the chamber. Such etchant may comprise a reducing species, an oxidizing species, one or more of: a halide, a fluoride, an alcohol, an amine, a phosphine, an alkene, an alkyne, carbon monoxide, a β-diketone (e.g., acetylacetone, hexafluoroacetylacetone, and/or tetramethylheptanedione), oxygen containing species, a chalcogen, or the like or combinations thereof. At block 214, the reaction chamber may be purged to remove excess etchant and/or byproducts of residue removal.

At block 216, it may be determined whether process 200 for removing organic residue or non-organic residue is complete. If process 200 is not complete, process 200 may return to operations at block 204 and cycle through operations in blocks 204-214.

In an example, the operations described in blocks 204-214 may be performed in any order and/or repeated. Thus, operations to be performed at block 212 may be performed prior to or subsequent to operations to be performed at blocks 204-206. Purge steps at blocks 208 and 214 are optional. As well as flowing a gas curtain at block 210.

Returning to block 216, if process 200 is complete, process 200 may proceed to block 218 where the process ends.

Compared to conventional methods, addition of a residue removal cycle to remove residue materials from the surface of substrate 114 and/or 116 using an etchant may improve throughput when a portion of the residue material is removed using an excited species. In an example, process 200 may be executed in cycles wherein a first cycle includes repeating one or more of operations at blocks 204-208 over a first time period, T1, to remove organic and/or non-organic materials from substrate 114 and/or substrate 116 surface. This phase may take longer than a second cycle to remove remaining organic and/or non-organic materials. The second cycle includes one or more of operations at blocks 210-212 performed over a second time period, T2. In an example, T1 may be greater than T2. The operation at block 210 may be executed during the full time period T2 or for a time less than the entire second time period T2.

FIG. 3A is a schematic diagram illustrating an example substrate processing system 300 configured to perform one or more substrate cleaning operations. Substrate processing system 300 includes a dual chamber module having two reaction chambers. In other examples, substrate processing system 300 may comprise a single chamber or any other number of chambers and claimed subject matter is not limited in this regard. For example, substrate processing system 300 may be a quad chamber module including four reaction chambers.

In an example, reaction chambers 302 and 304 may include respective susceptors 310 and 312 to support respective substrates 314 and 316 during surface cleaning, processing operations and/or other operations. Reaction chamber 302 and/or reaction chamber 304 may be coupled to a remote plasma unit 306 via transport tube 324 and chemical delivery line 382 putting reaction chamber 302 and/or reaction chamber 304 in fluid communication with remote plasma unit 306.

Remote plasma unit 306 may be coupled to one or more chemical source vessels 390 configured to supply a vapor phase reactant 392 to remote plasma unit 306 via chemical delivery line 348. Gas distribution systems 318 and 320 are configured to distribute a substance (e.g., vapor phase reactant 392, one or more other reactants, etchants and/or excited species) to respective surfaces of substrates 314 and 316. The vapor phase reactant 392 may be activated to generate an excited species, such as ions of hydrogen, argon, neon, krypton, nitrogen, helium, xenon, radon, chlorine, fluorine, oxygen, or the like, or a combination thereof to be used in one or more substrate cleaning operations (e.g., cleaning a surface of substrate 314 and/or 316). A skilled artisan will recognize that other ion species may be used and claimed subject matter is not limited in this regard.

Reaction chambers 302 and 304 may be direct plasma reaction chambers. Plasmas 329 and/or 331 may be formed directly over respective substrates 314 and/or 316 within reaction spaces 352 and/or 354.

To form plasmas 329 and/or 331, for example, potential difference across two electrodes is alternated at radio frequency (RF) to generate alternating fields in respective reaction spaces 352 and/or 354. This in turn generates a plasma discharge from vapor phase reactant 392 supplied to the reaction chambers 302 and/or 304 from remote plasma unit 306.

In the illustrated example, respective grounded electrodes 315 and 317 are provided within respective susceptors 310 and/or 312, while powered electrodes 319 and 321 are spaced above respective substrates 314 and/or 316 and connected to respective RF power sources 323 and 325. In various arrangements, powered electrodes 319 and 321 can be disposed in respective susceptors 314, 316, respective gas distribution systems 318 and/or 320, chamber walls and/or elsewhere within inner volumes 342 and/or 344. The skilled artisan will appreciate that power may be coupled to the vapor phase reactant 392 to generate excited species within the reaction space in other ways, such as by inductive coupling from coils outside the chamber, for example. Reactants for a direct plasma reactor can be supplied in any suitable manner and claimed subject matter is not limited in this regard.

In an example, excited species generated during a plasma phase may contact a surface of substrate 314 within reaction space 352 and/or a surface of substrate 316 within reaction space 354.

Substrate processing system 300 may include a vacuum source 322 for controlling vacuum pressure in one or more of reaction chambers 302 and 304. In another example, each chamber may have a vacuum source, rather than a shared vacuum source 322. After or as part of a surface cleaning operation cycle, excited species may be removed from reaction chamber 302 and/or 304. Such removal can be accomplished in a variety of ways, e.g., by turning off the power that generates the excited species, and/or by physical removal of the excited species (e.g., by purging, pump down, moving the substrate away from a zone in which the excited species is supplied, or combinations thereof). Vacuum source 322 may perform pump down or other purging to remove excited species from reaction chambers 302 and/or 304.

In an example, substrate processing system 300 may include delivery vessels 328 and 330. Delivery vessels 328 and/or 330 may be configured to store and deliver respective chemical species 336 and/or 338 to one or both reaction chambers 302 and 304 via respective chemical delivery lines 332 and/or 334. Delivery lines 332 and/or 334 may be coupled to transport tube 324 and may enter respective reaction chambers 302 and/or 304 via chemical delivery line 382. This puts delivery vessel 328 and/or 330 in fluid communication with reaction chamber 302 and/or 304. Chemical species 336 and/or 338 may be distributed to one or more of substrates 314 and 316 via respective gas distribution systems 318 and 320.

Chemical species 336 and/or 338 may be configured to remove material (e.g., unwanted organic or inorganic residue) from respective surfaces of substrate 314 and/or 316 during a substrate surface cleaning operation. Chemical species 336 and/or 338 may comprise an etchant (e.g., reducing agents, oxidizing agents, halides, fluorides, or the like, or combinations thereof) or other chemical reactants configured to remove material from a substrate 314 and/or 316 surface (e.g., alcohol containing species, oxygen containing species, chalcogen, or the like, or combinations thereof).

FIG. 3B is a diagram showing substrate 314 having a top surface 367, side surface 371 and bottom surface 373. Top surface 367, side surface 371 and bottom surface 373 may have various textures and/or surface features in or on which unwanted material may be disposed. Such unwanted material may be removed from top surface 367, side surface 371 and bottom surface 373 according to methods, systems and apparatus described herein.

Referring now to FIG. 3C, in an example controller 356 includes a device interface 362, a processor 364, a user interface 366, and a memory 368. The device interface 362 connects the processor 364 to the wired or wireless link 370. The processor 364 may be operably connected to the user interface 366 (e.g., to receive user input and/or provide user output therethrough) and may be disposed in communication with the memory 368. The memory 368 includes a non-transitory machine-readable medium having a plurality of program modules 372 recorded thereon containing instructions that, when read by the processor 364, cause the processor 364 to execute certain operations. Among the operations are operations of a substrate surface cleaning process (shown in FIG. 2 and FIG. 4).

In an example, controller 356 may be communicatively coupled to various devices within substrate processing system 300 including a reaction chamber (e.g., reaction chambers 302 and/or 304), a plasma source (e.g., remote plasma unit 106) and/or delivery vessel (e.g., delivery vessels 328 and/or 330) and may be configured to control the reaction chamber, plasma source, plasma generation and the delivery vessel so as to control removing organic residue or non-organic residue, or a combination thereof, from the surface of the substrate (e.g., substrates 114 and/or 116) during a substrate surface cleaning process.

In an example, controller 356 may further be communicatively coupled to valves 383, 384, 385, 386, 387, 388, 389, and/or 399 and/or sensors 393, 394, 395, 396, 397 and/or 398. Controller 356 may be configured to selectively control the flow of various chemicals, excited species, etchant and/or other substances into or out of the respective reaction chambers, delivery vessels and/or remote plasma units via valves 383, 384, 385, 386, 387, 388, 389, and/or 399. For example, valves 383 and 384 may be used to control the flow of respective ones of chemical species 336 and/or 338 into respective reaction chambers 302 and/or 304, while valves 389 and/or 399 may control flow of chemical species 336 and/or 338 into transport tube 324. Valves 387 and/or 388 may be used to control the flow of vapor phase reactant 392, and/or chemical species 336 and/or 338 into respective reaction chambers 302 and/or 304. Valves 385 and/or 386 may control vacuum pump/purge operations to remove materials from reaction chambers 302 and/or 304.

In an example, controller 356 may control the flow (including flow rate and/or duration of flow) of vapor phase reactant 392 to remote plasma unit 306, formation of plasma within reaction chamber 302 and/or 304, the flow (including flow rate and/or duration of flow) of etchant from the delivery vessels (e.g., delivery vessels 328 and/or 330) and/or removal of one or more chemicals and/or excited species from reaction chambers (e.g., reaction chambers 102 and/or 104) via a vacuum pump (not shown).

In an example, controller 356 may be configured to receive input signals from sensors disposed throughout substrate processing system 300 such as sensor 393 (disposed within remote plasma unit 306), sensor 394 (disposed within source vessel 390), sensors 395 and/or 396 (disposed within respective reaction chambers 302 and/or 304) and/or sensors 397 and/or 398 (disposed within respective delivery vessels 328 and/or 330). Such sensors may provide feedback data to controller 356, which can adjust various device parameters of the devices communicatively couple to controller 356 responsive to the feedback data. In some examples, sensors 393, 394, 395, 396, 397 and/or 398 may comprise pressure sensors, light sensors, temperature sensors, flow rate sensors and/or composition sensors, or the like or a combination thereof.

In operation, the controller 356 receives feedback data from one or more of the sensors (e.g., sensors 393, 394, 395, 396, 397 and/or 398). In an example, controller 356 may be operatively coupled to respective RF sources 323 and/or 325, power electrodes 319 and/or 321, grounded electrodes 315 and/or 317. In operation, the controller 356 receives feedback data from the sensors and adjusts RF power sources 323 and/or 325, the power electrodes 319 and/or 312, and the grounded electrodes 315 and/or 317 responsive to the feedback data to control plasma generation. Controller 356 may control plasma generation based on a set of predetermined instructions or based on real time feedback from the sensors. Controller 356 may use the feedback data to determine how to adjust device parameters to further control the substrate surface cleaning process described in FIGS. 2 and 4. In an example, the controller may adjust the device parameters based on a set of predetermined instructions or based on real time feedback from sensors 393, 394, 395, 396, 397 and/or 398. As will be appreciated by those of skill in the art in view of the present disclosure, the controller 356 may have a different arrangement in other examples and remain within the scope of the present disclosure.

FIG. 4 is a flow chart that depicts an example substrate surface cleaning process 400 for removing organic residue and/or non-organic residue from a surface (e.g., top surface 367) of a substrate (e.g., substrate 314 and/or substrate 316). In an example, process 400 will be described with reference to FIGS. 3A-3C.

Process 400 may begin at block 402, where the substrate 314 may be supported by a susceptor (e.g., susceptor 310 and/or susceptor 312) in a reaction chamber (e.g., reaction chamber 302 and/or reaction chamber 304) wherein the substrate 314 comprises a surface.

Process 400 may continue at block 404, where an excited species may be generated in a plasma. In an example, the excited species comprises ions. Such ions may comprise hydrogen, argon, neon, krypton, nitrogen, helium, xenon, radon, chlorine, fluorine, oxygen, or the like, or a combination thereof. The excited species may be generated by a direct plasma system as described with reference to FIG. 3A wherein reaction chambers 302 and 304 may be direct plasma reaction chambers and plasmas 329 and/or 331 may be formed directly over respective substrates 314 and/or 316 within reaction spaces 352 and/or 354. Alternatively, the excited species may be generated in a plasma within, for example, remote plasma units 106 and/or 108, as described above with respect to FIG. 1A, wherein the excited species may comprise radicals such as radicals of hydrogen, argon, nitrogen, chlorine, fluorine, chlorine, or oxygen or a combination thereof.

At block 406, the top surface of a substrate may be contacted with the excited species within the reaction chamber. At block 408, the reaction chamber may be purged to remove excess excited species and/or byproducts of residue removal.

At block 410, it may be determined whether process 400 for removing organic residue or non-organic residue with an excited species is complete. If process 400 is not complete, process 400 may return to operations at block 406 and cycle through operations in blocks 406-410. If process 400 is complete, process 400 may proceed to operations at block 412.

At block 412, the top surface of the substrate may be contacted with an etchant species within the chamber. Such etchant may comprise reducing and/or oxidizing species including: halides, alcohols, amines, phosphines, alkenes, alkynes, carbon monoxide, β-diketone (e.g., acetylacetone, hexafluoroacetylacetone, and/or tetramethylheptanedione), or the like or combinations thereof. Those skilled in the art will understand that the suitability of an etchant will depend on factors known in the art, including, the identity of the reduced or oxidized material, the identities of other materials present, etching conditions (e.g., temperature, pressure, time, activation), and the like.

At block 414, the reaction chamber may be purged to remove excess etchant and/or byproducts of residue removal.

At block 416, it may be determined whether process 400 for removing organic residue or non-organic residue is complete. If process 400 is not complete, process 400 may return to operations at block 412 and cycle through operations in blocks 412-416.

In an example, the operations described in blocks 404-416 may be performed in any order and/or repeated. Thus, operations to be performed at block 412 may be performed before or after operations to be performed at blocks 404-408. Purge steps at blocks 408 and 414 are optional.

Returning to block 416, if process 400 is complete, process 400 may proceed to block 418 where the process ends.

Compared to conventional methods, addition of a residue removal cycle to remove residue materials from the surface of substrate 314 and/or 316 using an etchant may improve throughput when a portion of the residue material is removed using an excited species. In an example, process 400 may be executed in cycles wherein a first cycle includes repeating one or more of operations at blocks 404-410 over a first time period, T1, to remove organic and/or non-organic materials from substrate 314 and/or substrate 316 surface. This phase may take longer than a second cycle to remove remaining organic and/or non-organic materials. The second cycle includes one or more of operations at blocks 412-416 performed over a second time period, T2. In an example, T1 may be greater than T2.

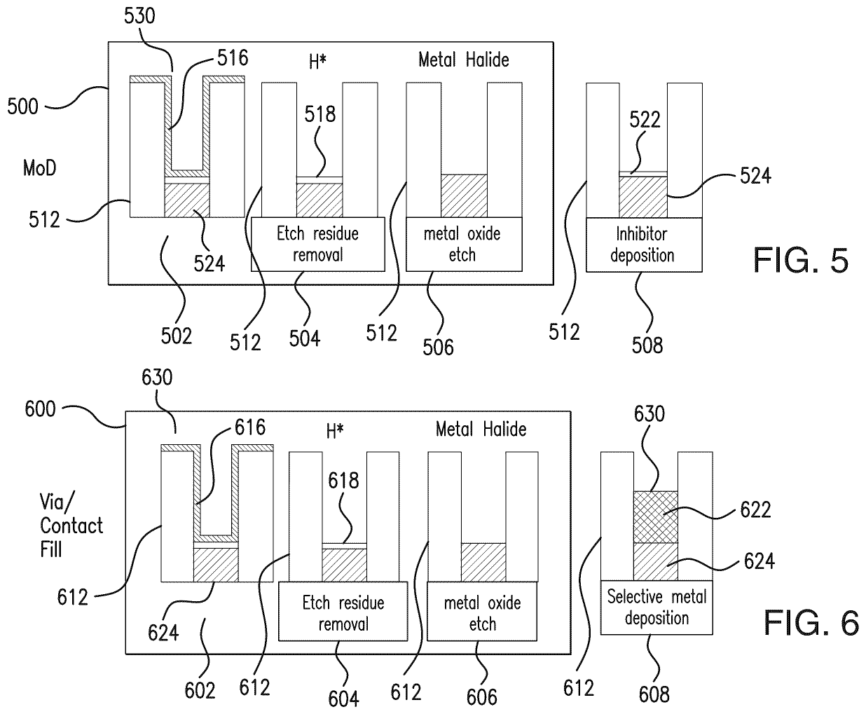

FIG. 5 is a schematic diagram illustrating an example process 500 for removing residue from a surface of a substrate 512. Process 500 will be described with reference to FIGS. 2 and 4. During process 500 a metal layer 524 (e.g., tungsten and/or molybdenum) is deposited on a dielectric material. A residue layer 516 may coat a feature 530 on substrate 512 surface. At operation 502 substrate 512 may be supported within a reaction chamber. At operation 504 residue layer 516 may be removed, for example, by process steps at blocks 204-208 of process 200 and/or process steps at blocks 404-410 of process 400. At operation 506, remaining residue or unwanted material such as metal oxide layer 518 (e.g., tungsten oxide and/or molybdenum oxide) may be removed, for example, by process steps at blocks 210-214 of process 200 and/or process steps at blocks 412-416. At operation 508, substrate 512 may proceed to further processing steps such as to have an inhibitor 522 deposited on metal layer 524.

FIG. 6 is a schematic diagram illustrating an example process 600 for removing residue from a surface of a substrate 612. Process 600 will be described with reference to FIGS. 2 and 4. During process 600 a metal layer 624 (e.g., tungsten oxide and/or molybdenum oxide) is deposited on a dielectric material. A residue layer 616 may coat a feature 630 on substrate 612 surface. At operation 602 substrate 612 may be supported within a reaction chamber. At operation 604 residue layer 616 may be removed, for example, by process steps at blocks 204-208 of process 200 and/or process steps at blocks 404-410 of process 400. At operation 606, remaining residue or unwanted material, such as oxide layer 618 may be removed, for example, by process steps at blocks 210-214 of process 200 and/or process steps 412-416. At operation 608, substrate 612 may proceed to further processing steps such as a via or gap fill operation wherein a metal layer 622 (e.g., tungsten and/or molybdenum) is deposited on metal layer 624. In an example, metal layer 622 may comprise a different material from metal layer 624.

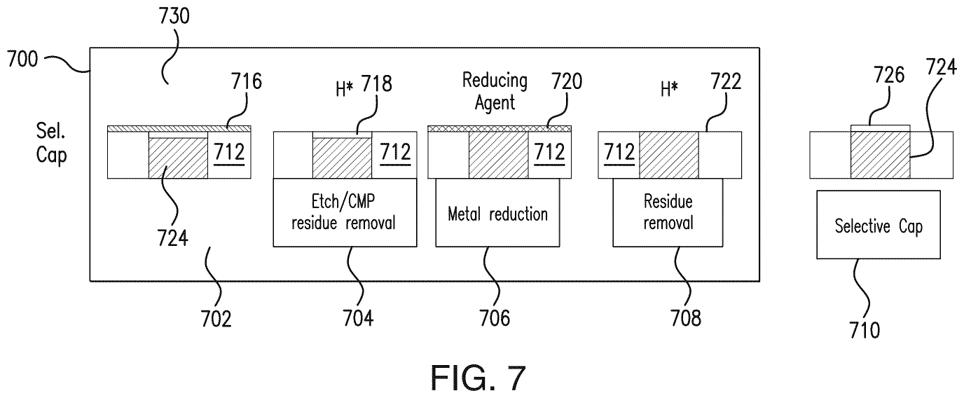

FIG. 7 is a schematic diagram illustrating an example process 700 for removing residue from a surface of a substrate 712. Process 700 will be described with reference to FIGS. 2 and 4. During process 700 a metal layer 724 (e.g., copper) is deposited on a dielectric material on substrate 712. A residue layer 716 may coat a feature 730 and a portion of a surface of substrate 712. At operation 702 substrate 712 may be supported within a reaction chamber. At operation 704 residue layer 716 may be removed, for example, by process steps at blocks 204-208 of process 200 and/or process steps at blocks 404-410 of process 400. At operation 706, r oxide layer 718 may be reduced, for example, by process steps at blocks 210-214 of process 200 and/or process steps 412-416 of process 400. At operation 708, remaining residue or unwanted material, such as layer 720, may be removed, by process steps at blocks 204-208 of process 200 and/or process steps at blocks 404-410 of process 400. At operation 710, substrate 712 may proceed to further processing steps such as a selective capping operation wherein a cap 726 is deposited on metal layer 724.

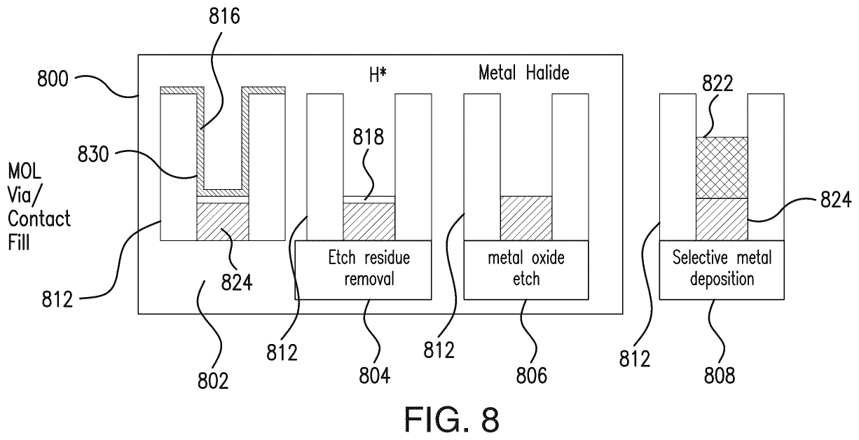

FIG. 8 is a schematic diagram illustrating an example process 800 for removing residue from a surface of a substrate 812. Process 800 will be described with reference to FIGS. 2 and 4. During process 800 a metal layer 824 (such as molybdenum and/or tungsten) is deposited on a dielectric material of substrate 812. A residue layer 816 may coat a feature 830 on substrate 812 surface. At operation 802 substrate 812 may be supported within a reaction chamber. At operation 804 residue layer 816 may be removed, for example, by process steps at blocks 204-208 of process 200 and/or process steps at blocks 404-410 of process 400. At operation 806, remaining residue or unwanted material, such as oxide layer 818 may be removed, for example, by process steps at blocks 210-214 of process 200 and/or process steps 412-416. At operation 808, substrate 812 may proceed to further processing steps such as a via or contact fill operation wherein a metal layer 822 is deposited on metal layer 824 (e.g., tungsten and/or molybdenum). In an example, metal layer 822 may comprise a different material from metal layer 824.

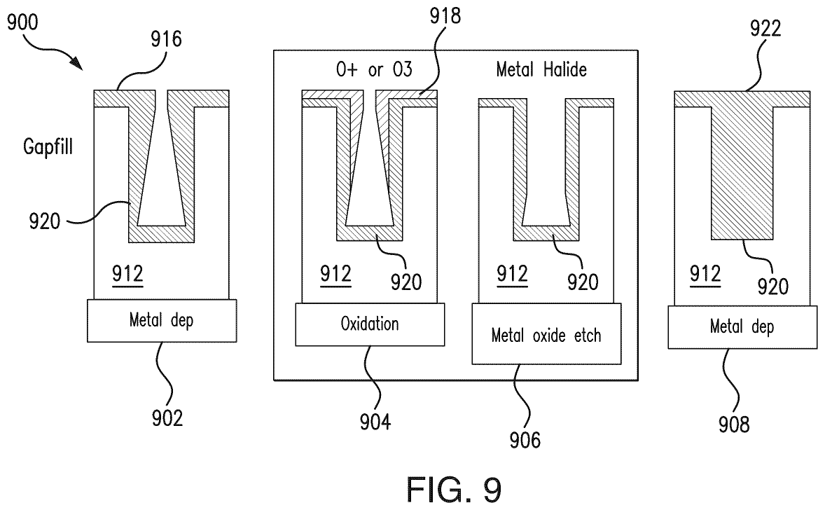

FIG. 9 is a schematic diagram illustrating an example process 900 for removing residue from a surface of a substrate 912. Process 900 will be described with reference to FIGS. 2 and 4. At operation 902, a substrate 912 may be supported within a reaction chamber. Substrate 912 may comprise a metal layer 916 deposited within feature 920. At operation 904, metal layer 916 is treated with O+ or O3 by process steps at blocks 204-208 of process 200 and/or process steps at blocks 404-410 of process 400 which leaves a metal oxide layer 918 coating the top portion of feature 920 on substrate 912 surface. At operation 906, metal oxide layer 918 may be removed, for example, by process steps at blocks 210-214 of process 200 and/or process steps at blocks 412-416. At operation 908, substrate 912 may proceed to further processing steps such as a via or gap fill operation wherein a metal layer 922 is deposited within feature 920.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The headings provided herein, if any, are for convenience only and do not necessarily affect the scope or meaning of the devices and methods disclosed herein.

1. A method comprising:
a) supporting a substrate in a chamber wherein the substrate comprises a surface;
b) contacting the surface of the substrate with an excited species within the chamber;
c) contacting the surface of the substrate with an etchant species within the chamber; and
removing organic residue or non-organic residue, or a combination thereof, from the surface of the substrate responsive to executing steps b and c.

2. The method of claim 1, wherein the etchant species is a reducing species, an oxidizing species, a halide, alcohol containing species, oxygen containing species, chalcogen, formaldehyde or a combination thereof.

3. The method of claim 1, wherein the excited species comprises a radical comprising hydrogen, argon, nitrogen, fluorine, chlorine, or oxygen or a combination thereof.

4. The method of claim 1, wherein the excited species comprises an ion comprising hydrogen, argon, neon, krypton, nitrogen, helium, xenon, radon, chlorine, fluorine, or oxygen or a combination thereof.

5. The method of claim 1, further comprising, d) purging the chamber.

6. The method of claim 5, wherein a first cycle including step b is performed over a first time period, T₁ and a second cycle including step c is performed over a second time period, T₂.

7. The method of claim 6, wherein T₁ is greater than T₂.

8. The method of claim 7, wherein the excited species is generated by a remote plasma unit in fluid communication with the chamber.

9. The method of claim 8, further comprising flowing an inert gas at a positive pressure from the remote plasma unit into the chamber during T₂.

10. The method of claim 9, wherein the inert gas is flowed into the chamber during T₂ for a time less than the entire second time period.

11. The method of claim 9, wherein the inert gas curtain is flowed into the chamber during T₂ over the entire second time period.

12. A substrate processing system, comprising:
a first reaction chamber including a first substrate support for supporting a first substrate;
a first plasma source in fluid communication with the first reaction chamber; and
a first delivery vessel in fluid communication with the first reaction chamber.

13. The substrate processing system of claim 12, further comprising:
a second reaction chamber including a second substrate support for supporting a second substrate;
a second plasma source in fluid communication with the second reaction chamber;
the first delivery vessel in fluid communication with the second reaction chamber; and
a second delivery vessel in fluid communication with the first reaction chamber and the second reaction chamber.

14. The substrate processing system of claim 13, wherein the first plasma source and the second plasma source comprise a first remote plasma unit and a second remote plasma unit, respectively, wherein the first remote plasma unit and the second remote plasma unit are configured to generate radicals to contact the first substrate and the second substrate.

15. The substrate processing system of claim 14, further comprising:
a first transport tube coupled between the first remote plasma unit and the first reaction chamber;
a second transport tube coupled between the second remote plasma unit and the second reaction chamber;
a first chemical gas line coupled to the first delivery vessel, the first transport tube and the second transport tube; and
a second chemical gas line coupled to the second delivery vessel, the first transport tube and the second transport tube.

16. The substrate processing system of claim 12, further comprising:
a second reaction chamber including a second substrate support;
the first remote plasma unit in fluid communication with the second reaction chamber;
the first delivery vessel in fluid communication with the second reaction chamber; and
a second delivery vessel in fluid communication with the first reaction chamber and the second reaction chamber.

17. The substrate processing system of claim 16, further comprising:
wherein the first delivery vessel is in fluid communication with the first reaction chamber via a first chemical gas line; and
wherein the second delivery vessel is in fluid communication with the second reaction chamber via a second chemical gas line.

18. The substrate processing system of claim 16, wherein the first plasma source is configured to generate ions within the first reaction chamber and wherein a gas distribution device or the first substrate support comprise an electrode for forming the ions for a direct plasma surface treatment of the first substrate within the reaction chamber.

19. A substrate processing system, comprising:
a reaction chamber including a substrate support for supporting a substrate wherein the substrate comprises a surface;
a plasma source in fluid communication with the reaction chamber configured to contact the surface of the substrate with an excited species within the chamber;
a delivery vessel in fluid communication with the reaction chamber configured to contact the surface of the substrate with an etchant species within the chamber; and
a controller coupled to the reaction chamber, the plasma source, and the delivery vessel configured to control the plasma source and the delivery vessel so as to control removing organic residue or non-organic residue, or a combination thereof, from the surface of the substrate.

20. The substrate processing system of claim 19, further comprising a plurality of sensors, wherein the controller is configured to control the removing the organic residue or the non-organic residue, or a combination thereof, from the surface of the substrate based on data from each of the plurality of sensors.

21. The substrate processing system of claim 19, further comprising, a vacuum pump configured to purge the reaction chamber subsequent to the excited species contacting the surface of the substrate, or subsequent to the etchant species contacting the surface of the substrate, or a combination thereof,
wherein the controller is coupled to the vacuum pump and is further configured to control the purging of the chamber so as to control removing the organic residue or the non-organic residue, or a combination thereof, from the surface of the substrate.

22. The substrate processing system of claim 19, wherein the removing organic residue or non-organic residue, or a combination thereof, from the surface of the substrate is executed, by the controller, in at least a first cycle including flowing the excited species to the surface of the substrate from the plasma source in a first time period, T₁ and a second cycle including flowing the etchant species to the surface of the substrate from the delivery vessel in a second time period, T₂.
